(19) United States
(12) Patent Application Publication
(10) Pub. No.: US 2023/0256924 A1
(43) Pub. Date: Aug. 17, 2023

(54) CIRCUIT FILTER NETWORK

(71) Applicant: Panasonic Automotive Systems Company of America, Division of Panasonic Corporation of North America, PEACHTREE CITY, GA (US)

(72) Inventor: GORDON RAY MILLER, NEWNAN, GA (US)

(21) Appl. No.: 18/107,480

(22) Filed: Feb. 8, 2023

Related U.S. Application Data
(60) Provisional application No. 63/309,384, filed on Feb. 11, 2022.

(51) Int. Cl. B60R 16/03; H02M 1/44; B60L 53/20; H03H 1/00

(52) U.S. Cl. CPC B60R 16/03; H02M 1/44; B60L 53/20; H03H 1/0007

(57) ABSTRACT

Examples of the disclosure relate to systems and methods for reducing EMI in electrical systems. The electrical system can include a DC power source and a load component to receive direct-current (DC) electrical energy from the DC power source through a DC bus. The system also includes a filter network coupled to the DC bus between the DC power source and the load component to suppress electromagnetic interference (EMI) on the DC bus. The filter network includes a first capacitor and at least a second capacitor conductively coupled in series with one another between the positive voltage line and the ground line of the DC bus. Additionally, the capacitance of the first capacitor is different from the capacitance of the second capacitor. The capacitance values of the two capacitors are selected to provide a desired performance characteristic for suppressing EMI.

### CROSS-REFERENCE TO RELATED APPLICATIONS

This application claims the benefit of U.S. Provisional Application No. 63/309,384, filed on Feb. 11, 2022, which the disclosure of which is hereby incorporated by reference in its entirety for all purposes.

### FIELD OF THE INVENTION

The present disclosure generally relates to a method, system, and device for reducing ElectroMagnetic Interference (EMI). More specifically, the present disclosure describes a filter network for reducing EMI in electrical systems.

### BACKGROUND

This section is intended to introduce the reader to various aspects of art, which may be related to various aspects of the present disclosure, which are described and/or claimed below. This discussion is believed to be helpful in providing the reader with background information to facilitate a better understanding of the various aspects of the present disclosure. Accordingly, it can be understood that these statements are to be read in this light, and not as admissions of prior art.

Modern vehicles typically come equipped with a wide variety of electronic systems. Some electronic devices may have a tendency to produce electromagnetic interference that can propagate through conductors and cause Radio Frequency Interference (RFI). Electromagnetic interference, if not controlled, can cause disturbances in some electronic circuits and degrade their performance.

### SUMMARY

The present disclosure generally relates to techniques for reducing EMI in electrical systems, such as vehicular electrical systems. An example electrical system for a vehicle includes a direct-current (DC) power source, such as a battery, and a load component to receive DC electrical energy from the DC power source through a DC bus that includes a positive voltage line and ground line. The electrical system also includes a filter network coupled to the DC bus between the DC power source and the load component and configured to suppress electromagnetic interference (EMI) on the DC bus. The filter network includes a first capacitor and at least a second capacitor conductively coupled in series with one another between the positive voltage line and the ground line. The first capacitor has a first capacitance value and the second capacitor has a second capacitance value different from the first capacitance value. The first capacitance value and the second capacitance value are selected to provide a desired performance characteristic for suppressing EMI.

An example filter network for suppression of electromagnetic interference (EMI) in accordance with embodiments includes a first capacitor and at least a second capacitor conductively coupled in series with one another between a direct-current (DC) positive voltage line and a ground line. The first capacitor has a first capacitance value and the second capacitor has a second capacitance value different from the first capacitance value. The first capacitance value and the second capacitance value are selected to provide a desired performance characteristic for suppressing EMI.

An example filter network for suppression of electromagnetic interference (EMI) in accordance with embodiments includes a first leg comprising a first capacitor and at least a second capacitor conductively coupled in series with one another between a direct-current (DC) positive voltage line and a ground line. The first capacitor has a first capacitance value and the second capacitor has a second capacitance value different from the first capacitance value. The filter network includes a second leg in parallel with the first leg, the second leg comprising a third capacitor and at least a fourth capacitor conductively coupled in series with one another between the positive voltage line and the ground line. The third capacitor has a third capacitance value and the fourth capacitor has a fourth capacitance value different from the third capacitance value. The first leg and the second leg are conductively coupled to one another through a conductive element. The conductive element is coupled to the first leg between the first capacitor and the second capacitor and coupled the second leg between the third capacitor and the fourth capacitor.

### BRIEF DESCRIPTION OF THE DRAWINGS

The above-mentioned and other features and advantages of the present disclosure, and the manner of attaining them, may become apparent and be better understood by reference to the following description of one example of the disclosure in conjunction with the accompanying drawings, where:

FIG. 1 is a block diagram of an electrical system disposed in a vehicle in accordance with embodiments;

FIG. 2 is an example of a shunt filter network in accordance with embodiments;

FIGS. 3A and 3B are other examples of shunt filter networks in accordance with embodiments;

FIGS. 4A and 4B are other examples of shunt filter networks in accordance with embodiments;

FIG. 5 is a graph of impedance versus frequency for an example shunt filter network impedance in accordance with the embodiment shown in FIG. 2;

FIG. 6 is a graph of impedance versus frequency for an example shunt filter network impedance in accordance with the embodiment shown in FIG. 3A; and

FIG. 7 is a graph of impedance versus frequency for an example shunt filter network in accordance with the embodiment shown in FIG. 4B.

Correlating reference characters indicate correlating parts throughout the several views. The exemplifications set out herein illustrate examples of the disclosure, in one form, and such exemplifications are not to be construed as limiting in any manner the scope of the disclosure.

### DETAILED DESCRIPTION OF EXAMPLES

One or more specific examples of the present disclosure are described below. In an effort to provide a concise description of these examples, not all features of an actual implementation are described in the specification. It can be appreciated that in the development of any such actual implementation, as in any engineering or design project, numerous implementation-specific decisions may be made to achieve the developers' specific goals, such as compliance with system-related and business-related constraints, which may vary from one implementation to another. Moreover, it can be appreciated that such a development effort might be complex and time consuming, and is a routine undertaking of design, fabrication, and manufacture for those of ordinary skill having the benefit of this disclosure.

This disclosure describes techniques for reducing electromagnetic interference in electrical systems. One technique for reducing electromagnetic interference involves the use of shunt capacitors coupled across the power supply, i.e., between the positive supply voltage and ground. The bypass capacitor appears as a low resistance at certain frequencies and therefore shunts electrical energy at those frequencies to ground. The effectiveness of the bypass capacitor depends on various factors including the electrical response of the capacitor, which is very frequency specific. The present disclosure describes improved filter networks that can be more easily tailored to provide specific EMI suppression characteristics. Embodiments of the present techniques may provide benefits in electrical systems of vehicles.

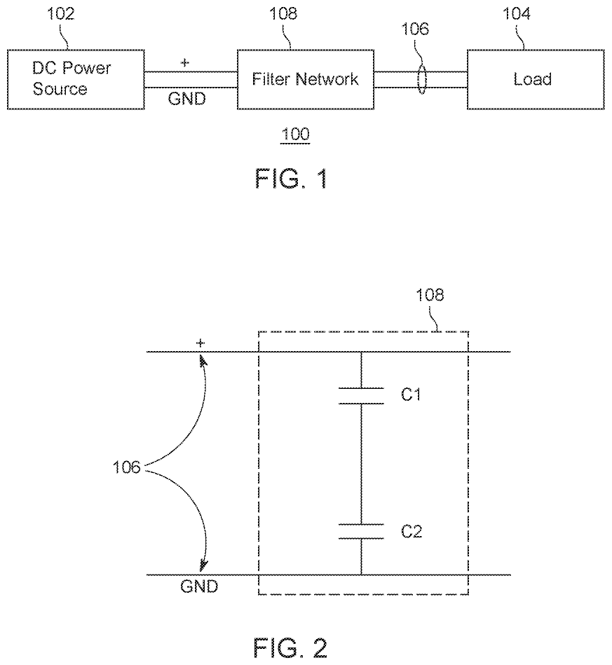

FIG. 1 is a block diagram of an electrical system disposed in a battery powered device in accordance with embodiments. The system 100 may be included in any suitable type of vehicles including airplanes, boats, and passenger vehicles such as cars, trucks, Sport Utility Vehicles (SUVs), vans, and others. The vehicle may also be a combustion engine vehicle, an electric battery vehicle, or a hybrid thereof. The system 100 may also be included in any type of portable battery-powered device, such as a laptop or a smart phone, for example.

The system 100 includes a DC power source 102 that provides a source of Direct Current (DC) electrical power with a source impedance. The DC power source 102 may be a battery such as a lead-acid battery in the case of a combustion engine vehicle, or an electric vehicle battery such as a lithium ion battery in the case of electric vehicles. The DC power source 102 may also be a switching power converter, such as a DC to DC converter or an Alternating Current (AC) to DC converter.

The DC power source 102 is coupled to a load component 104 through a DC bus 106. The load component 104 may be any of a variety of electronic devices deployed in a vehicle. For example, the load component 104 may be any type of electronic control unit (ECU) such as an engine control module (ECM), body control module (BCM), and others. The load component may also be a wireless communications module such as WiFi interface module or Bluetooth interface module, or other Radio Frequency (RF) module, for example. The load component 104 may also be an automotive head unit, sometimes referred to as an infotainment system. Other load components are also possible. Moreover, it will be appreciated that in a typical system, the DC power source 102 will be coupled to several such load components.

The load component 104 may include one or more of various electronic devices capable of generating electromagnetic interference. For example, the load component 104 may include a power inverter to convert the DC electrical energy provided by the DC power source 102 to Alternating Current (AC) electrical energy for powering elements of the load component 104. The load component 104 may include a power converter such as a switch mode power supply to step the voltage level provided by the DC power source 102 up or down to a new DC voltage level suitable for elements of the load component 104. The load component 104 may also include one or more electrical motors, RF transmitters, sound speakers, display devices, and others. The electromagnetic interference generated by the load component 104 may manifest as an AC signal that back propagates onto the DC bus 106. The characteristics of the AC signal will depend on the design of the devices generating the interference, and can be determined through testing.

The system 100 also includes a filter network 108 configured to suppress electromagnetic interference that may be generated by the load component 104. The filter network 108 is able to suppress the interference by shunting AC signals to ground, thereby eliminating or reducing the magnitude of the AC signals that pass through the filter network 108 to the DC power source 102 and to other components coupled to the DC bus 106. The filter network 108 is also bidirectional, meaning that AC signals from other components coupled to the DC bus 106 may be suppressed before reaching the load component 104. Examples of a filter network 108 in accordance with embodiments are described more fully in relation to FIGS. 2-4.

It will be appreciated that the architecture shown in FIG. 1 is one example architecture that can be used to implement the disclosed techniques. A suitable architecture in accordance with embodiments is not limited to the specific form or division of functions described in relation to FIG. 1. For example, the filter network 108 may be included in the load component 104. Additionally, it is to be understood that the block diagram of FIG. 1 is not intended to indicate that the system 100 is to include all of the components shown in FIG. 1. Rather, the system 100 can include fewer or additional components not illustrated in FIG. 1.

FIG. 2 is an example of a filter network in accordance with embodiments. As shown in FIG. 2, the filter network 108 includes a pair of capacitors coupled in series between the positive voltage line (+) and the ground line (GND) parallel to the load component. The pair of capacitors are referred to herein as C1 and C2 to signify that the capacitance of C1 is selected to be different from the capacitance of C2.

One advantage of using a pair of series coupled capacitors is that it provides protection in the event of failure. If one of the capacitors fails, the remaining capacitor will prevent a short circuit across the DC bus 106. A typical failure mode for a capacitor coupled to a printed circuit board involves flexing of the circuit board in a manner that degrades the physical integrity of the capacitor. Accordingly, such capacitors are often disposed on the circuit board at a 90 degree angle to one another to reduce the likelihood that both capacitors will be subjected to the same stress. Providing series capacitors in a filter network in this way is typically only done to provide protection in the event of failure, not to achieve a specific electrical response. In fact, it is an industry standard practice to for each capacitor in the series to be of the same capacitance value, due to undesirable electrical effects that may result from using different capacitances in series.

In accordance with embodiments disclosed herein, the specific values of C1 and C2 may be selected to provide a desired electrical response. In an actual implementation, the characteristics of the electromagnetic interference will usually be known, and will be more prevalent at a specific frequency or range of frequencies. The filter network 108 can be tuned through proper selection of the capacitance values of C1 and C2 to provide improved EMI suppression at the frequencies of interest. Specifically, proper selection of the capacitance values will result in a very low impedance at the frequency range of the electromagnetic interference. For example, the notch frequency (i.e., the frequency at which the impedance of the filter network is lowest) can be shifted to a higher or lower frequency to match the frequency characteristics of the electromagnetic interference through proper selection of typical commercially available capacitance values, depending in part on the expected load current and the position of the filter network 108 in the system 100, which has an effect on the source and load impedance. The choice of capacitance values will vary due to the design considerations of a particular embodiment and will often be a tradeoff between space, cost, and frequencies generated by the load 104. In some embodiments, C1 may have a capacitance of 10 picoFarad (pF) to 10 nanoFarad (nF), and C2 may have a capacitance of 10 pF to 10 nF, with C2 being approximately 50 pF to 50 nF higher or lower than C1. For example, in some embodiments, C1 may have a capacitance of 100 nF and C2 may have a capacitance of 150 nF. It will be appreciated that other capacitance values may be selected depending on the design considerations of a particular embodiment. For example, the present techniques may be used with capacitance values up to 10 microFarads (μF) and higher.

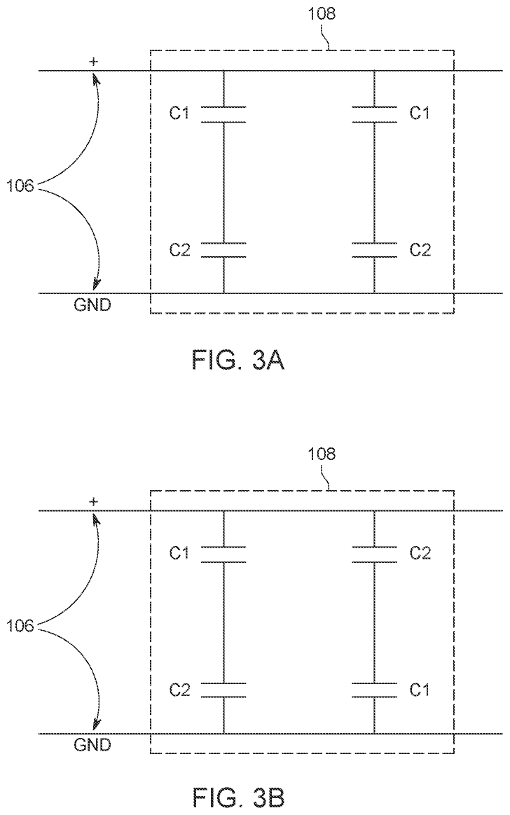

FIG. 3A is another example of a filter network in accordance with embodiments. The filter network 108 of FIG. 3A includes two filter legs coupled in parallel to one another and parallel to the load component. Each filter leg includes a pair of capacitors coupled in series between the positive voltage source and ground. As in FIG. 2, the pair of capacitors are referred to herein as C1 and C2 to signify that the capacitance of C1 is different from the capacitance of C2. In this embodiment, each filter leg includes capacitors with the same capacitance value (i.e., C1=C1 and C2=C2). One advantage of providing two filter legs is that the overall impedance of the filter network 108 is reduced at the frequencies of interest, thereby further reducing the targeted electromagnetic interference. As described in relation to FIG. 2, the specific values of C1 and C2 may be selected to provide a desired electrical response. Additionally, in some embodiments, the capacitance values of the first leg may be different from the capacitance values of the second leg.

FIG. 3B is another example of a filter network in accordance with embodiments. The filter network 108 shown in FIG. 3B is generally similar to the filter network 108 shown in FIG. 3A. However, the filter network shown in FIG. 3B employs capacitors having values of C1 and C2 in one of the parallel filter legs and capacitors having values of C2 and C1 in a second parallel filter leg. Moreover, the capacitors C2 and C1 in the second parallel filter leg of the embodiment shown in FIG. 3B are reversed or opposite relative to the capacitors C1 and C2 in the first parallel filter leg of the embodiment shown in FIG. 3B.

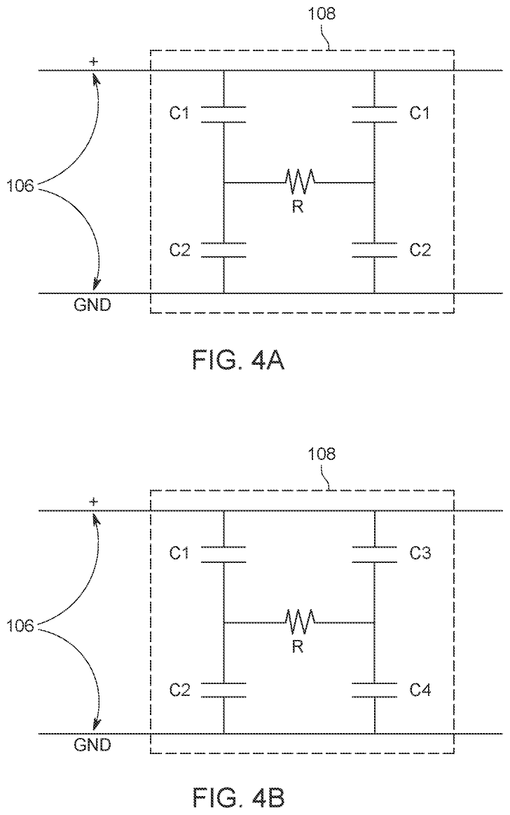

FIG. 4A is another example of a filter network in accordance with embodiments. The filter network of FIG. 4A is generally similar to the filter circuit of FIG. 3A in that it includes two filter legs coupled in parallel to one another and parallel to the load component, and each filter leg includes a pair of capacitors coupled in series between the positive voltage line and ground line. As in FIG. 3A, the capacitance value of C1 is different from the capacitance value of C2, and each filter leg includes capacitors with the same capacitance values (i.e., C1=C1 and C2=C2). Accordingly, the filter circuit of FIG. 4A is similar to the filter circuit of FIG. 3A. However, in this embodiment, the filter circuit includes a conductive coupling through a conductive element between the two legs at the connection point between the capacitors in each leg. The specific values of C1, C2, and R may be selected to provide a desired electrical response. Although the conductive element shown in FIG. 4A is a resistor, it will be appreciated that other conductive elements may be used instead of or in addition to the resistor, including linear and non-linear devices. For example, the conductive element may include one or more of the following: resistors, thermistors, diodes, Zener diodes, and others. Those of ordinary skill in the art will appreciate that the values of the capacitors C1 and C2 in the first parallel filter leg of FIG. 4A may be reversed in the second parallel filter leg of FIG. 4A.

FIG. 4B is another example of a filter network in accordance with embodiments. The filter network 108 shown in FIG. 4B is generally similar to the filter network 108 shown in FIG. 4A. However, the filter network shown in FIG. 4B employs capacitors having values of C1 and C2 in one of the parallel filter legs and capacitors having values of C3 and C4 in a second parallel filter leg. The values of the capacitors C1, C2, C3 and C4 may all be different from each other in some embodiments. Alternatively, any combination of the values C1, C2, C3 and C4 may be equal to each other in other embodiments.

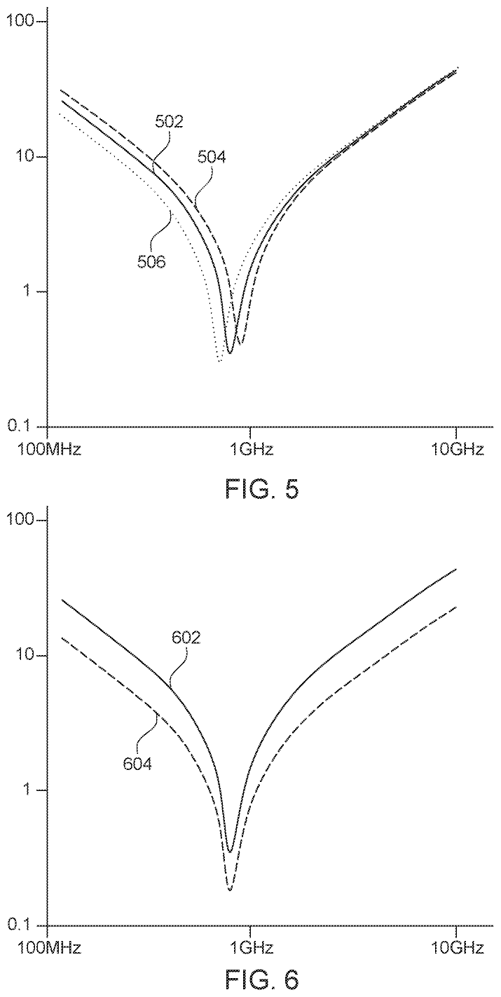

Those of ordinary skill in the art will appreciate that the filter embodiment shown in FIG. 4B enables the value of R to be changed in order to change the bandwidth and impedances in the band stop. This is the effect of a differential voltage across R. 100321 FIG. 5 is a graph of impedance versus frequency for an example filter network in accordance with the embodiment shown in FIG. 2. The Y-axis represents the magnitude of the impedance in Ohms across the filter network (positive to ground) and the X-axis represents frequency in Gigahertz. Curve 502 represents simulated impedance values for a filter network with a single pair of series capacitors as shown in FIG. 2. It will be appreciated that reducing the impedance of the filter network increases the degree to which Alternating-Current (AC) signals will be shunted to ground, resulting in a reduction of EMI. In this example, capacitor C1 has a value of 150 picofarads and capacitor C2 has a value of 100 picofarads.

For reference, FIG. 5 also shows curves for a filter network with a single pair of series capacitors similar to the embodiment of FIG. 2, with the difference that both capacitors are the same value. In particular, curve 504 shows a filter network in which both capacitors have a value of 100 picofarads (2×100 picofarad), and curve 506 shows a filter network in which both capacitors have a value of 150 picofarads (2×150 picofarad). As can be seen in FIG. 5, the selection of differently valued series capacitors (curve 502) has the effect of moving the notch frequency to an intermediate value between the notch frequencies achievable with the 2×100 picofarad and 2×150 picofarad filter networks. This may be especially useful when a specific performance curve is desired that is not achievable with standard off-the-shelf capacitors.

FIG. 6 is a graph of impedance versus frequency for an example filter network in accordance with the embodiment shown in FIG. 3A. As in FIG. 5, the Y-axis represents the magnitude of the impedance in Ohms across the filter network and the X-axis represents frequency in Gigahertz. For reference, curve 602 represents the simulated impedance values for the filter network with a single pair of series capacitors as shown in FIG. 2 and represented by curve 502 in FIG. 5.

Curve 604 shows a filter network with two legs of parallel capacitors as shown in FIG. 3. For each leg, capacitor C1 has a value of 150 picofarads and capacitor C2 has a value of 100 picofarads. As can be seen in FIG. 6, adding an additional set of parallel capacitors to the filter network reduces the impedance across the range of frequencies while maintaining the same notch frequency, thus providing additional EMI suppression at the frequencies of interest.

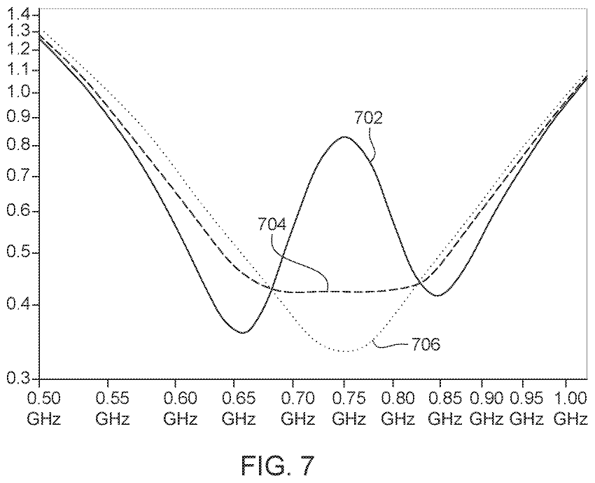

FIG. 7 is a graph of impedance versus frequency for an example filter network in accordance with the embodiment shown in FIG. 4B. As in FIGS. 5 and 6, the Y-axis represents the magnitude of the impedance in Ohms across the filter network and the X-axis represents frequency in Gigahertz. As in FIG. 6, the capacitance values for capacitors C1 and C2 are 150 picofarads and 100 picofarads, respectively. The values for capacitors C3 and C4 are 100 picofarads and 150 picofarads, respectively.

Curve 702 represents the simulated impedance values for the filter network with the resistor, R, equal to 100 milliohm, curve 704 represents the simulated impedance values for the filter network with the resistor, R, equal to 500 milliohms, and curve 706 represents the simulated impedance values for the filter network with the resistor, R, equal to 1 Ohm. The capacitance values of C1 and C2 are the same for each curve. The capacitance values of C3 and C4 are the same for each curve.

As can be seen in FIG. 7, increasing the resistance of resistor, R, has the effect of broadening the achievable pass band and reducing the ripple, which may be useful for targeting a broader range of EMI frequencies. Thus, the resistance of resistor R may be selected to achieve a target pass band for the filter network. At some higher values of R, the filter network may be configured exhibit two notch frequencies, which may be useful when there are two main EMI frequencies that are to be targeted by the filter network. By contrast, lower values of R may cause a slight broadening of the pass band while still maintaining a lower minimum notch impedance. To summarize, adding the resistor, R, to the filter network as shown in FIG. 5 provides an additional tuning parameter that can be adjusted to obtain a specific filter performance.

It will be appreciated the performance characteristics shown on FIGS. 5-7 are shown by way of example only, and that the performance of the filter network can be adjusted as desired for a particular implementation. For example, the particular capacitance values can be modified depending on the frequencies of interest to be suppressed. Additionally, a filter network in accordance with embodiments could have additional series capacitors and additional parallel legs of the series capacitors. Furthermore, the curves represent simulated impedance values, and the actual performance of the demonstrated filter networks may vary due to non-ideal performance characteristics of actual electrical components.

While the invention may be susceptible to various modifications and alternative forms, specific embodiments have been shown by way of example. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. An electrical system for a vehicle, comprising:
a DC power source;
a load component to receive direct-current (DC) electrical energy from the DC power source through a DC bus comprising a positive voltage line and a ground line; and
a filter network coupled to the DC bus between the DC power source and the load component and configured to suppress electromagnetic interference (EMI) on the DC bus;
wherein the filter network comprises:
a first capacitor and at least a second capacitor conductively coupled in series with one another between the positive voltage line and the ground line;
wherein the first capacitor has a first capacitance value and the second capacitor has a second capacitance value different from the first capacitance value; and
wherein the first capacitance value and the second capacitance value are selected to provide a desired performance characteristic for suppressing EMI.

2. The electrical system of claim 1, wherein the first capacitor and the second capacitor comprise a first leg of the filter network, wherein the filter network comprises a second leg in parallel with the first leg, and wherein the second leg comprises:
a third capacitor and at least a fourth capacitor conductively coupled in series with one another between the positive voltage line and the ground line; and
wherein the third capacitor has a third capacitance value and the fourth capacitor has a fourth capacitance value different from the third capacitance value.

3. The electrical system of claim 2, wherein the third capacitance value is equal to the first capacitance value, and the fourth capacitance value is equal to the second capacitance value.

4. The electrical system of claim 2, wherein the first leg and the second leg are conductively coupled to one another through a resistor, wherein the resistor is coupled at one end between the first capacitor and the second capacitor and coupled at an other end between the third capacitor and the fourth capacitor.

5. The electrical system of claim 4, wherein a resistance value of the resistor is selected to achieve a target pass band for the filter network.

6. The electrical system of claim 5, wherein the resistance value is between 100 milliohms and 1 ohm.

7. The electrical system of claim 1, wherein the first capacitance value is between 10 pF and 10 nF, and the second capacitance value is between 10 pF and 10 nF.

8. The electrical system of claim 1, wherein the first capacitance value is 50 pF to 50 nF higher or lower than the second capacitance value.

9. The electrical system of claim 1, wherein the load component comprises an electronic device that generates the EMI to be suppressed by the filter network.

10. The electrical system of claim 1, wherein the load component is a wireless communications module.

11. A filter network for suppression of electromagnetic interference (EMI), comprising:
a first capacitor and at least a second capacitor conductively coupled in series with one another between a direct-current (DC) positive voltage line and a ground line;
wherein the first capacitor has a first capacitance value and the second capacitor has a second capacitance value different from the first capacitance value; and
wherein the first capacitance value and the second capacitance value are selected to provide a desired performance characteristic for suppressing EMI.

12. The filter network of claim 11, wherein the first capacitor and the second capacitor comprise a first leg of the filter network, wherein the filter network comprises a second leg in parallel with the first leg, and wherein the second leg comprises:
a third capacitor and at least a fourth capacitor conductively coupled in series with one another between the positive voltage line and the ground line; and
wherein the third capacitor has a third capacitance value and the fourth capacitor has a fourth capacitance value different from the third capacitance value.

13. The filter network of claim 12, wherein the third capacitance value is equal to the first capacitance value, and the fourth capacitance value is equal to the second capacitance value.

14. The filter network of claim 12, wherein the first leg and the second leg are conductively coupled to one another through a resistor, wherein the resistor is coupled to the first leg between the first capacitor and the second capacitor and coupled the second leg between the third capacitor and the fourth capacitor.

15. The filter network of claim 14, wherein a resistance value of the resistor is selected to achieve a target pass band for the filter network.

16. The filter network of claim 15, wherein the resistance value is between 100 milliohms and 1 ohm.

17. The filter network of claim 11, wherein filter network is coupled to a load component comprising an electronic device that generates the EMI to be suppressed by the filter network.

18. The filter network of claim 17, wherein the load component is a wireless communications module.

19. A filter network for suppression of electromagnetic interference (EMI), comprising:
a first leg comprising a first capacitor and at least a second capacitor conductively coupled in series with one another between a direct-current (DC) positive voltage line and a ground line, wherein the first capacitor has a first capacitance value and the second capacitor has a second capacitance value different from the first capacitance value; and
a second leg in parallel with the first leg, the second leg comprising a third capacitor and at least a fourth capacitor conductively coupled in series with one another between the positive voltage line and the ground line, wherein the third capacitor has a third capacitance value and the fourth capacitor has a fourth capacitance value different from the third capacitance value; and
wherein the first leg and the second leg are conductively coupled to one another through a conductive element, wherein the conductive element is coupled to the first leg between the first capacitor and the second capacitor and coupled the second leg between the third capacitor and the fourth capacitor.

20. The filter network of claim 19, wherein the conductive element is a resistor.
